(19) United States
(12) Patent Application Publication
(10) Pub. No.: US 2010/0107975 A1
(43) Pub. Date: May 6, 2010

(54) APPARATUS FOR TRANSFERRING WAFER CARRIER AND SYSTEM FOR FABRICATING SEMICONDUCTOR HAVING THE SAME

(76) Inventor: Kil Ho Jung, Gwangju (KR)

Correspondence Address: BIRCH STEWART KOLASCH & BIRCH, PO BOX 747, FALLS CHURCH, VA, 22040-0747, US

(21) Appl. No.: 12/530,634

(22) PCT Filed: Jun. 20, 2008
(86) PCT No.: PCT/KR08/03509

§ 371 Date: Sep. 10, 2009

(30) Foreign Application Priority Data
Jun. 22, 2007 (KR) 10-2007-0061428

(51) Int. Cl. H01L 21/677; H01L 21/461

(52) U.S. Cl. 118/500; 414/222.01; 257/E21.483

(57) ABSTRACT

Provided are a wafer carrier transferring apparatus and a semiconductor conductor fabricating system having the wafer carrier transferring apparatus. The wafer carrier transferring apparatus comprises an arm pocket portion supporting a wafer carrier and a pocket end portion detachably coupled to opposite ends of the arm pocket portion.

### TECHNICAL FIELD

Embodiments relate to an apparatus for transferring a wafer carrier and a system for fabricating a semiconductor using the wafer transferring apparatus.

### BACKGROUND ART

A semiconductor device is fabricated to have a plurality of thin films that are formed on a wafer by selectively repeatedly performing a variety of processes such as an etching process, a diffusing process, a chemical vapor deposition process, an ion implanting process, a metal deposition process, and the like.

In order to grow the thin films on the wafer, a variety of apparatuses such as a metal organic chemical vapor deposition (MOCVD) apparatus, a chemical vapor deposition (CVD) apparatus, an electron beam deposition apparatus, a physical vapor deposition (PVD) apparatus, a plasma laser deposition (PLD) apparatus, a dual-type thermal evaporator, a sputtering apparatus, a metal organic chemical vapor deposition (MOCVD) apparatus, and the like may be used.

In the growing apparatuses, the wafer is loaded or unloaded on a wafer carrier (or a susceptor). The wafer carrier is transferred to a process chamber or the like by a transferring apparatus. The semiconductor thin films are formed on the wafer in the process chamber into and from which a variety of gases are supplied and discharged.

### DISCLOSURE OF INVENTION

### Technical Problem

Embodiments provide a wafer carrier transferring apparatus that is designed to replace only end portions of a transferring arm by coupling replaceable pocket ends to the opposite ends of the transferring arm, and a semiconductor fabricating system having the wafer carrier transferring apparatus.

Embodiments provide a wafer carrier transferring apparatus that is designed to protect a transferring arm from external impact by coupling fragile pocket ends to the opposite ends of the transferring arm, and a semiconductor fabricating system having the wafer carrier transferring apparatus.

Embodiments provide a wafer carrier transferring apparatus that is designed to protect a transferring arm from external impact by making an inner surface of an arm pocket portion of the transferring arm inclined so that a wafer carrier can be supported on the inner surface of the arm pocket, and a semiconductor fabricating system having the wafer carrier transferring apparatus.

### Technical Solution

An embodiment provides a wafer carrier transferring apparatus comprising: an arm pocket portion supporting a wafer carrier and a pocket end portion detachably coupled to opposite ends of the arm pocket portion.

An embodiment provides a wafer carrier transferring apparatus comprising: an arm pocket portion supporting the wafer carrier; a pocket end portion coupled to opposite ends of the arm pocket portion and formed of a glass material; and a fixing portion for coupling the pocket end portion to the opposite ends of the arm pocket portion.

An embodiment provides a semiconductor fabricating system comprising: at least one load lock chamber in which a wafer carrier is stored; at least one process chamber in which a thin film is grown on a wafer loaded on the wafer carrier; and a transfer chamber comprising a wafer carrier transferring apparatus transferring the wafer carrier between the load lock chamber and the process chamber.

The wafer carrier transferring apparatus comprises an arm pocket portion supporting a wafer carrier; and a pocket end portion detachably coupled to opposite ends of the arm pocket portion.

### ADVANTAGEOUS EFFECTS

According to the embodiments, a problem that an end of the transferring arm is drooped down can be solved.

According to the embodiments, even when external impact is applied, only the pocket ends are damaged and the affection of the external impact on the motor or the transferring arm can be minimized.

According to the embodiments, since an inclined surface is formed inside the arm pocket portion of the transferring arm, the movement of the wafer carrier supported on the inclined surface of the arm pocket portion can be minimized when the external impact is applied, thereby protecting the wafer carrier.

### BRIEF DESCRIPTION OF THE DRAWINGS

FIG. 1 is a schematic view of a semiconductor fabricating system according to a first embodiment.

FIG. 2 is a top plane view of a transferring apparatus of FIG. 1.

FIG. 3 is a perspective view of an inner pocket portion of FIG. 2.

FIGS. 4A and 4B are front and side-sectional views of the inner pocket portion of FIG. 3.

FIG. 5 is an exploded perspective view of an outer pocket portion, pocket end portion, and fixing portion of FIG. 2.

FIG. 6 is an assembled top plane view of FIG. 5.

FIG. 7 is an assembled rear view of FIG. 5.

FIG. 8 is an assembled cross-sectional view of FIG. 5.

FIG. 9 is an assembled longitudinal sectional view of the outer pocket portion and pocket end portion of FIG. 5.

FIG. 10 is an exploded perspective view of a modified example of the outer pocket portion, pocket end portion, and fixing portion of FIG. 2.

FIG. 11 is an exploded perspective view of another modified example of the outer pocket portion, pocket end portion, and fixing portion of FIG. 2.

FIG. 12 is a longitudinal-sectional view of the pocket end portion of FIG. 11.

### BEST MODE FOR CARRYING OUT THE INVENTION

Hereinafter, embodiments will be described with reference to accompanying drawings.

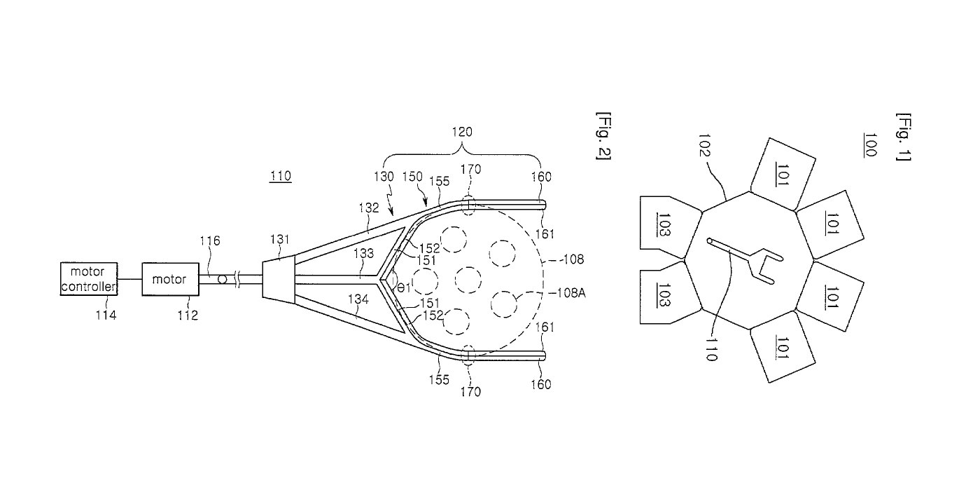

FIG. 1 is a schematic view of a semiconductor fabricating system according to a first embodiment.

Referring to FIG. 1, a semiconductor system 100 comprises one or more load lock chambers 101, a transfer chamber 102 comprising a transferring apparatus 110, and one or more process chambers 103.

The load lock chambers 101 function as a buffer for storing wafer carriers (or susceptors). That is, the load lock chambers 101 function as a buffer that can temporarily store the wafer carriers when the wafer carriers are loaded in or unloaded from the process chambers 103. The load lock chambers 101 are arranged along a circumference of the transfer chamber 102.

In the process chambers 103, the semiconductor thin films are grown on the wafer loaded on the wafer carrier by supplied gases through predetermined processes.

Here, a variety of apparatuses such as a metal organic chemical vapor deposition

(MOCVD) apparatus, a chemical vapor deposition (CVD) apparatus, an electron beam deposition apparatus, a physical vapor deposition (PVD) apparatus, a plasma laser deposition (PLD) apparatus, a dual-type thermal evaporator, a sputtering apparatus, a metal organic chemical vapor deposition (MOCVD) apparatus, and the like may be used to grow the thin films on the wafer. However, the present embodiment is not limited to them.

The transfer chamber 102 comprises the transferring apparatus 110. The transferring apparatus 110 takes the wafer carrier out of the load lock chamber 101 and loads the wafer carrier into the process chamber 103 or takes the wafer carrier out of the process chamber 103 and unloads the wafer carrier to an external side or the load lock chamber 101. The transferring apparatus 110 may be referred to as a transferring robot. For the descriptive convenience, it will be referred to as a transferring apparatus in the following description. In addition, in this embodiment, although the transferring apparatus 110 is comprised in the transfer chamber 102, the transferring apparatus 110 may be installed on a cassette stage or a standby loader chamber. The number of the transferring apparatuses and the installing location of the transferring apparatuses may vary but are not specifically limited.

FIG. 2 is a detailed top plane view of the transferring apparatus of FIG. 1.

Referring to FIG. 2, the transferring apparatus 110 comprises a motor 112, a motor controller 114, and a transferring arm 120.

The motor 112 drives the transferring arm 120 in accordance with the control of the motor controller 114.

The motor 112 is connected to the transferring arm 120 by a link unit 116 that transfers torque of the motor 112 to the transferring arm 120. This torque transferring structure may vary but is not limited to the above configuration. The structure of the motor 112 and motor controller 114 may not be comprises in the transferring apparatus 110 or the transfer chamber 102 of FIG. 1 and it not specifically limited.

The transferring arm 120 comprises a supporting portion 130, an arm pocket portion 150, a pocket end portion 160, and a fixing portion 170.

The supporting portion 130 supportably connects the link portion 116 to the arm pocket portion 150. The supporting portion 130 comprises a body 131 connected to the link unit 116 and a plurality of supports 132, 133, and 134 branched off from the body 131.

The body 131 transfers the torque from the link unit 116 to the supports 132, 133, and 134. The supports 132, 133, and 134 uniformly transfer the torque from the body 131 to the arm pocket portion 150.

The body 131, supports 132, 133, and 134, and arm pocket portion 150 may be integrally formed of metal such as stainless steel.

The support 133 may be referred to as center support branched off from a center of the body 131. The supports 132 and 134 may be referred to as side supports branched off from both sides of the body 131. However, the supports are not limited to these configurations.

The side supports 132 and 134 are obliquely formed with respect to the center support 133. That is, distances between the side support 132 and the center support 133 and between the side support 134 and the center support 133 increase as they goes away from the body 131.

The arm pocket portion 150 comprises an inner pocket portion 151 and an outer pocket portion 155. An outer circumference of the wafer carrier 108 is supported by the arm pocket portion 150. The pocket end portions 160 are coupled to extreme ends of the arm pocket portion 150. The inner pocket 151 is supported by not only the center support 133 but also the side supports 132 and 134. The inner pocket 151 may be formed in a semicircular shape, a bow shape, or a bent shape (e.g., V-shape). However, the present disclosure is not limited to this configuration. That is, the inner pocket 151 has a center formed at a connecting portion of the center support 133 and bent toward ends of the side supports 132 and 134 at a predetermined angle or with a predetermined curvature.

An interior angle θ1 of the inner pocket 151 may be 100-130° within which an outer circumference of the wafer carrier 108 on which the wafer 108A is loaded can partly contact the inner pocket 151. Here, a plurality of the wafers 108A may be loaded on the wafer carrier 108. However, the present disclosure is not limited to this.

The outer pocket portion 155 extends from a connecting portion of the inner pocket portion 151 and the side supports 132 and 134. Here, the inner portion of the outer pocket portion 155 may be formed to have a curvature corresponding to an outer circumference of the wafer carrier 108. Here, an inner curvature of the outer pocket portion 155 is equal to or less than a curvature of an outer circumference of the wafer carrier 108.

The pocket end portions 160 are coupled to the extreme ends of the pocket outer portion 155 in parallel with each other. The pocket end portions 160 are spaced apart from each other by a distance less than a diameter of the wafer carrier 108.

The coupling portions of the outer pocket portion 155 and the pocket end portions 160 are formed in corresponding shapes (e.g., stepped shapes or groove and protrusion shapes). In addition, the extreme ends of the outer pocket portion 155 and first ends of the pocket end portions 160 are respectively provided with corresponding stepped structures or groove and protrusion structures.

The pocket end portions 160 are detachably mounted on the both ends of the aim pocket portion 150 or the extreme ends of the outer pocket portion 155 so that it is replaceable. The pocket end portions 160 may be formed of a material that can be broken when impact higher than a predetermined intensity. For example, the pocket end portions 160 may be formed of quartz.

The fixing portion 170 is designed such that the pocket end portions 160 are respectively coupled to the extreme ends of the outer pocket portion 155. The fixing portion 170 may be formed of an adhesive member such as an adhesive or viscosity material or a coupling member such as a screw or rivet.

Inclined surfaces 152 are formed on inner surfaces of the inner pocket 151 and the outer pocket portion. Inclined surfaces 161 are formed on inner surfaces of the pocket end portions 160. The inclined surfaces 152 and 161 are provided in the form of an extending state. The inclined surfaces 152 and 161 are formed at an angle that can contact the outer circumference of the wafer carrier 108 as large as possible.

By disposing the pocket ends 160 formed of a glass material on the opposite ends of the transferring arm 120 or on the opposite ends of the arm pocket portion 150, the pocket end portions 160 can be easily broken when the pocket end portions 160 or the transferring arm 120 collides with a wall or other objects. That is, since the pocket end portions 160 are broken by external impact, the affect of the external impact on the motor 112 or the transferring arm 120 can be minimized. In addition, even when the pocket end portions are broken, the carrier transferring apparatus can be used by simply replacing the pocket end portions.

Further, when the pocket end portions 160 or the wafer carrier 108 collides with the wall or other stations, the wafer carrier 108 is pushed rearward and the pocket end portions 160 may be broken. At this point, the movement of the wafer carrier 108 supported on the inclined surface 152 of the arm pocket portion 150 is minimized. That is, the inclined surface 152 protects the wafer carrier 108. Therefore, the wafer carrier 108 and the transferring arm 120 can be protected.

Further, when the external impact is applied to the wafer carrier 108 or the arm pocket portion 150, the transferring arm 120 stops in an interlock state by its sensor.

Even when the transferring arms 120 are used for many hours, the problem that the ends of the transferring arm 120, i.e., the pocket end portions 160 droop can be solved.

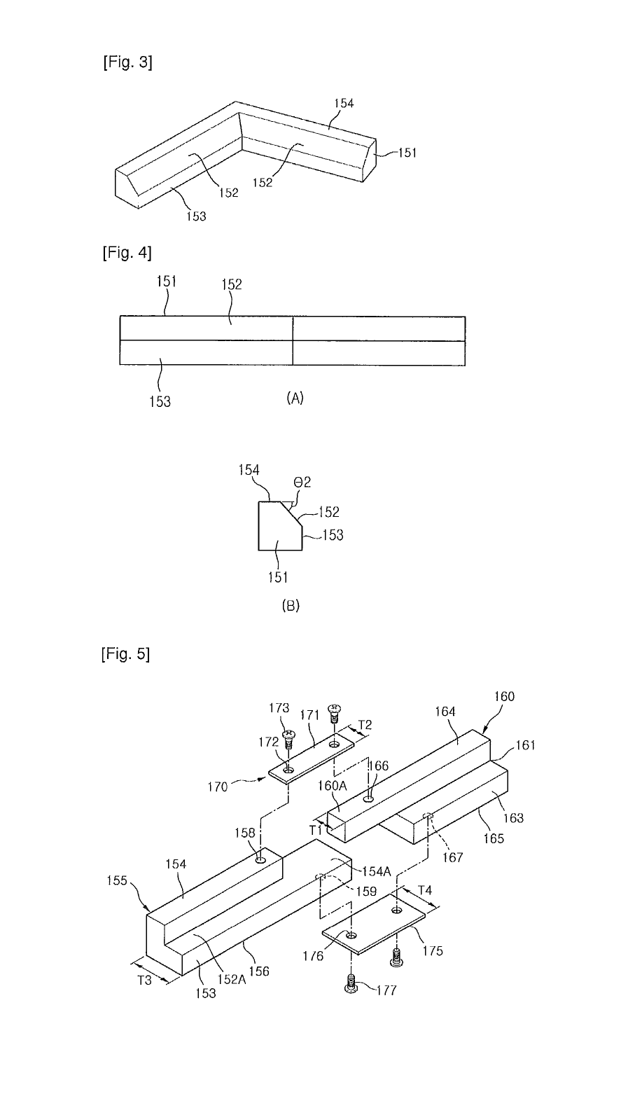

FIG. 3 is a perspective view of an inner pocket portion of FIG. 2 and FIGS. 4A and 4B are respectively front and side-sectional views of the inner pocket portion of FIG. 3.

Referring to FIGS. 3 and 4, the inner pocket portion 151 is designed such that the inclined surface 152 is formed between the top surface 154 and the inner surface 153. The inclined surface 152 is formed at a predetermined angle θ2 of, for example, 30-60° with respect to an extending line of the top surface 154 as shown in FIG. 4B. That is, the inner inclined surface 152 of the inner pocket portion 151 is formed at an angle which can be contacted a part of the outer circumference of the wafer carrier.

A width of the top surface 154 or inner surface 153 of the inner pocket portion 151 may vary in accordance with the inclined angle of the inclined surface 152 of the inner pocket portion 151.

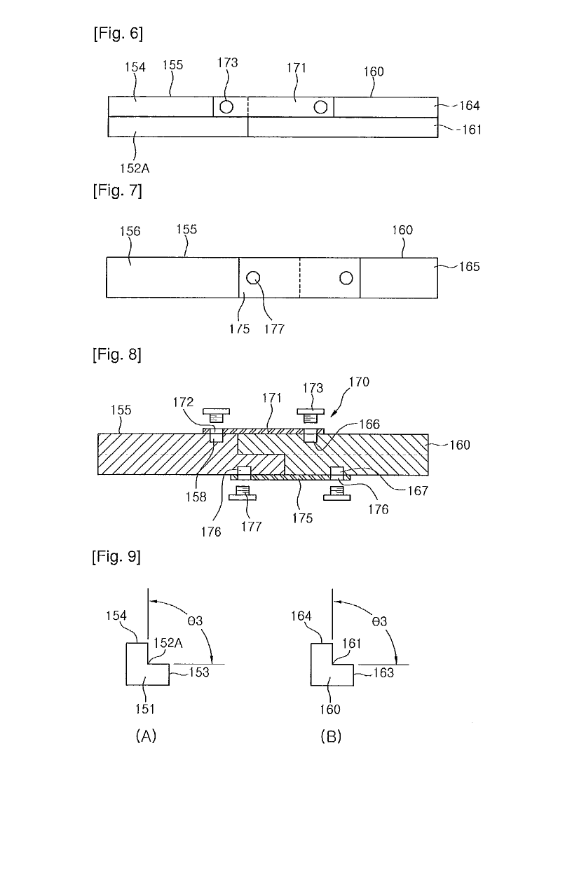

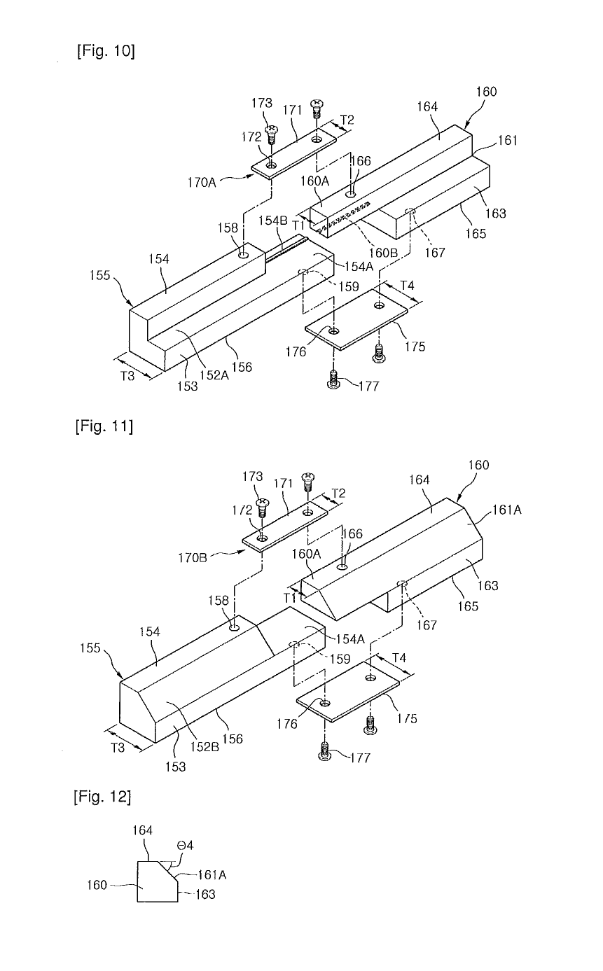

FIG. 5 is an exploded perspective view of the outer pocket portion, pocket end portion, and fixing portion of FIG. 2, FIG. 6 is an assembled top plane view of FIG. 5, FIG. 7 is an assembled rear view, FIGS. 9A and 9B are assembled longitudinal-sectional view, and FIG. 10 is an exploded perspective view.

Referring to FIG. 5, the extreme end 154a of the outer pocket portion 155 and the first end 160A of the pocket end portion 160 are correspondingly coupled to each other. That is, the extreme end 154a and the first end 160A are stepped in the vertical direction or formed to have a groove and a protrusion. Here, the extreme end 154A of the outer pocket portion 155 has an upper portion that is cut and the first end 160A of the pocket end portion 160 has a lower portion that is cut. The stepped locations, stepped structure, and stepped shape of the outer pocket portion 155 and pocket end portion 160 may change with each other and are not limited to the embodiment.

The extreme end 154A of the outer pocket portion 155 is coupled to the first end 160A of the pocket end portion 160 by closely contacting the first end 160A of the pocket end portion 160.

The outer pocket portion 155 is provided with first and second screw holes 158 and 159 and the pocket end portion 160 is provided with third and fourth screw holes 166 and 167. The first screw hole 158 is formed through the top surface 154 of the outer pocket portion 155 and the second screw hole 159 is formed through the undersurface 156 of the outer pocket portion 155. The third screw hole 166 is formed through the top surface 164 of the pocket end portion 160 and the fourth screw hole 167 is formed through the undersurface 165 of the pocket end portion 160.

Referring to FIGS. 5 and 8, a first fixing plate 171 closely contacts the top surfaces of the outer pocket portion 155 and the pocket end portion 160 and a second fixing plate 175 closely contacts the under surfaces of the outer pocket portion 155 and the pocket end portion 160.

The first fixing plate 171 is provided with fifth screw holes 172 corresponding to the first and third screw holes 158 and 166 and the second fixing plate 175 is provided with sixth screw holes 176 corresponding to the second and fourth screw holes 159 and 167.

Referring to FIGS. 5, 6, and 8, first screws 173 are coupled to the first and third screw holes 158 and 166 through the fifth screw holes 172 of the first fixing plate 171. That is, the first fixing plate 171 is fixed on the top surface 154 of the outer pocket portion 155 and the top surface 164 of the pocket end portion 160 by the first screws 173.

Referring to FIGS. 5 to 8, second screws 177 are coupled to the second and fourth screw holes 159 and 167 through the sixth screw holes 176 of the second fixing plate 175. That is, the second fixing plate 175 is fixed on the undersurface 156 of the outer pocket portion 155 and the undersurface 165 of the pocket end portion 160 by the second screws 177.

Referring to FIG. 8, the first and second fixing plates 171 and 175 integrally clamp the outer pocket portion 155 and the pocket end portion 160. Here, the first and second fixing plates 171 and 175 and the first and second screws 175 and 177 are exemplarily provided for the fixing portion 170 of FIG. 2. However, the fixing portion 170 may be provided in an attaching structure using an adhesive or viscosity material or formed in a combination structure of the attaching structure and the coupling structure. For example, the upper portions of the outer pocket portion 155 and the pocket end portion 160 may be attached to each other by the adhesive and the lower portions of the outer pocket portion 155 and the pocket end portion 160 may be coupled to each other by the fixing plate and screws. The fixing portion may variously provided. That is, the fixing portion is not limited to the above-described configurations. In addition, instead of fixing the upper and lower portions of the outer pocket portion 155 and the pocket end portion 160, the front and rear portions may be fixed.

Referring to FIG. 5, a width T1 of the top surface of the pocket end portion 160 may be identical to or different from a width T2 of the first fixing plate 171. A width T3 of the outer pocket portion 155 may be identical to or different from a width T4 of the second fixing plate 175. The widths are not specifically limited.

The first and second fixing plates 171 and 175 may be formed of metal such as stainless steel or a glass material. When the pocket end portion 160 is broken by the external impact, the fixing plates 171 and 175 formed of the metal is not damaged but the fixing plates 171 and 175 formed of the glass material are broken.

FIG. 9 is a longitudinal-sectional view of the outer pocket portion and the pocket end portion.

Referring to FIG. 9A, a portion 152A between the top surface 154 and inner surface 153 of the outer pocket portion 155 is stepped or inclined. Here, an angle θ3 between the top surface 154 and the inner surface 153 of the outer pocket portion 155 may be 90° or less.

A portion 161 between the top surface 164 and inner surface 163 of the pocket end portion 160 may be stepped or inclined. Here, an angle θ3 between the top surface 164 and the inner surface 163 of the pocket end portion 160 may be 90° or less. The angle θ3 may be identical to or different from the angle θ2 of the inclined surface 152 of the inner pocket portion 151 of FIG. 4B.

By coupling the pocket end portions 160 formed of the glass material to the opposite ends of the outer pocket portion 155, the damage or bending of the transferring arm 120 can be prevented as the pocket end portions 160 is easily broken when colliding with the wall or other objects. Even when the pocket end portion 160 is broken, the apparatus can be used by simply replacing the pocket end portion 160.

FIG. 10 is an exploded perspective view of a modified example of the outer pocket portion, pocket end portion, and fixing portion of FIG. 2.

Referring to FIG. 10, a fixing portion 170A comprises fixing plates 171 and 175 and a protrusion 154B, and a groove 160B. The protrusion 154B is formed on a top surface of the extreme end portion 154A of the outer pocket portion 155. The groove 160B corresponding to the protrusion 154B is formed on an undersurface of the end portion 160A of the pocket end portion 160. The protrusion 154B formed on the top surface of the extreme end portion 154A of the outer pocket portion 155 and the groove 160B formed on the undersurface of the end portion 160A of the pocket end portion 160 are engaged with each other to minimize the movement of the pocket end portion 160. The forming locations and shapes of the protrusion 154B and the groove 160B may vary and are not limited to the above-described configuration.

FIG. 11 is an exploded perspective view of another modified example of the outer pocket portion, pocket end portion, and fixing portion of FIG. 2, and FIG. 12 is a longitudinal-sectional view of the pocket end portion of FIG. 11. In the description of this modified example, parts same as those of FIG. 5 will refer to FIG. 5 and a detailed description thereof will be omitted herein.

Referring to FIGS. 11 and 12, an inclined surface 152B is formed between the top surface 154 and inner surface 153 of the outer pocket portion 155. An inclined angle of the inclined surface 152B may be 30-60° with respect to the top surface 154 of the outer pocket portion 155.

An inclined surface 161A is formed between the top surface 164 and inner surface 163 of the pocket end portion 160. At this point, as shown in FIG. 11, the inclined angle θ4 of the inclined surface 161A may be 30-60° with respect to the top surface 164 of the pocket end portion 161. At this point, the angle of the inclined surface 152B of the outer pocket portion 155 may be identical to or different from the angle θ4 of the inclined surface 161A of the pocket end portion 160.

As described above, by disposing the pocket end portions 160 formed of the glass material on the opposite ends of the outer pocket portion 155, the damage or bending of the transferring arm 120 can be prevented as the pocket end portions 160 is easily broken when colliding with the wall or other objects. Even when the pocket end portion 160 is broken, the apparatus can be used by simply replacing the pocket end portion 160.

While the present disclosure has been described and illustrated herein with reference to the preferred embodiments thereof, it will be apparent to those skilled in the art that various modifications and variations can be made therein without departing from the spirit and scope of the disclosure. Thus, it is intended that the present disclosure covers the modifications and variations of this disclosure that come within the scope of the appended claims and their equivalents.

### INDUSTRIAL APPLICABILITY

Embodiments can solve a problem that an end of the transferring arm is drooped down.

According to the embodiments, even when external impact is applied, only the pocket ends are damaged and the affection of the external impact on the motor or the transferring arm can be minimized.

Since embodiments form the inclined surface on an inner surface of the arm pocket portion of the transferring arm, the movement of the wafer carrier supported on the inclined surface of the arm pocket portion can be minimized when the external impact is applied, thereby protecting the wafer carrier.

1. A wafer carrier transferring apparatus comprising:
an arm pocket portion supporting a wafer carrier; and
a pocket end portion detachably coupled to opposite ends of the arm pocket portion.

2. The wafer carrier transferring apparatus according to claim 1, wherein the pocket end portion is formed of a material comprising a glass material.

3. The wafer carrier transferring apparatus according to claim 1, wherein the opposite ends of the arm pocket portion are correspondingly coupled to one ends of the pocket end portion, respectively.

4. The wafer carrier transferring apparatus according to claim 1, wherein the opposite ends of the arm pocket portion are fixed, coupled, or attached to one ends of the pocket end portion by a fixing portion, respectively.

5. The wafer carrier transferring apparatus according to claim 1, comprising fixing plate disposed on a top surface and undersurface of each of the pocket end portion and the arm pocket portion and a coupling unit coupled to the arm pocket portion and the pocket end portion through the fixing plate.

6. The wafer carrier transferring apparatus according to claim 1, wherein an inclined surface for supporting the wafer carrier is formed on an inner surface of the arm pocket portion.

7. The wafer carrier transferring apparatus according to claim 6, wherein an inclined surface is formed on an inner surface of the pocket end portion and angle of the inner surfaces of the arm pocket portion and the pocket end portion is 90° or 30-60° .

8. The wafer carrier transferring apparatus according to claim 1, wherein the arm pocket portion is formed in a semicircular shape or bent at a predetermined angle to correspond to an outer circumference of the wafer carrier.

9. The wafer carrier transferring apparatus according to claim 1, comprising:
a plurality of supports supporting the arm pocket portion;
a body from which the supports are branched off; and
a motor connected to the body.

10. The wafer carrier transferring apparatus according to claim 5, wherein the fixing plate is formed of stainless steel or glass.

11. A wafer carrier transferring apparatus comprising:
an arm pocket portion supporting the wafer carrier;
a pocket end portion coupled to opposite ends of the arm pocket portion and formed of a glass material; and
a fixing portion for coupling the pocket end portion to the opposite ends of the arm pocket portion.

12. The wafer carrier transferring apparatus according to claim 11, wherein inclined surfaces for supporting the wafer carrier are formed on inner surfaces of the arm pocket portion and the pocket end portion.

13. The wafer carrier transferring apparatus according to claim 11, wherein the end of the arm pocket portion is cut at an upper portion and one end of the pocket end portion is cut at a lower portions so that the arm pocket portion and the pocket end portion are correspondingly coupled to each other at the cutting portions.

14. The wafer carrier transferring apparatus according to claim 13, wherein a protrusion is formed on one of cut surfaces of the arm pocket portion and the pocket end portion and a groove corresponding to the protrusion are formed on the other of the cut surfaces of the arm pocket portion and the pocket end portion.

15. The wafer carrier transferring apparatus according to claim 11, wherein the fixing portion comprises fixing plate disposed on surfaces of the arm pocket portion and the pocket end portion and a coupling unit coupled to the arm pocket portion and the pocket end portion through the fixing plate.

16. A semiconductor fabricating system comprising:
at least one load lock chamber in which a wafer carrier is stored;
at least one process chamber in which a thin film is grown on a wafer loaded on the wafer carrier; and
a transfer chamber comprising a wafer carrier transferring apparatus transferring the wafer carrier between the load lock chamber and the process chamber,
wherein the wafer carrier transferring apparatus comprises an arm pocket portion supporting a wafer carrier; and a pocket end portion detachably coupled to opposite ends of the arm pocket portion.

17. The semiconductor fabricating system according to claim 16, wherein the arm pocket portion is formed of stainless steel and the pocket end portion is formed of a glass material.

18. The semiconductor fabricating system according to claim 16, comprising inclined surfaces are formed on inner surfaces of the arm pocket portion and the pocket end portion.

19. The semiconductor fabricating system according to claim 16, comprising a fixing portion for fixing the pocket end portion to the opposite ends of the arm pocket portion, wherein the fixing portion comprises fixing plate disposed on surfaces of the arm pocket portion and the pocket end portion and a coupling unit coupled to the arm pocket portion and the pocket end portion through the fixing plate.

20. The semiconductor fabricating system according to claim 16, wherein the opposite ends of the arm pocket portion and one ends of the pocket end portion are correspondingly coupled to each other by a protrusion-groove structure.
